(19) United States
(12) Patent Application Publication
(10) Pub. No.: US 2026/0025906 A1
(43) Pub. Date: Jan. 22, 2026

(54) CIRCUIT BOARD ASSEMBLY

(71) Applicant: Bitmain Technologies Inc., Beijing (CN)

(72) Inventors: Yang LI, Beijing (CN); Peng ZHAO, Beijing (CN); Shitao TIAN, Beijing (CN); Te PI, Beijing (CN); Haidie CHEN, Beijing (CN)

(73) Assignee: Bitmain Technologies Inc., Beijing (CN)

(21) Appl. No.: 19/342,591

(22) Filed: Sep. 28, 2025

Related U.S. Application Data
(63) Continuation of application No. PCT/CN2024/075323, filed on Feb. 1, 2024.

(30) Foreign Application Priority Data
Mar. 28, 2023 (CN) 202310317356.7

(51) Int. Cl. H05K 1/02

(52) U.S. Cl. CPC H05K 1/0203; H05K 1/0215; H05K 1/0256; H05K 2201/066; H05K 2201/10651

(57) ABSTRACT

The present disclosure provides a circuit board assembly, relating to the field of electronic devices, the circuit board assembly includes: a circuit board; a chip, fixedly connected to the circuit board; a current-carrying component, fixedly connected to the circuit board; a heat dissipation component, fixedly connected to the chip and the current-carrying component. The heat dissipation component of this circuit board assembly has a larger connection area, which improves the connection reliability of the heat dissipation component.

### CROSS-REFERENCE TO RELATED APPLICATIONS

The present application is a continuation of International Application No. PCT/CN2024/075323, filed on Feb. 1, 2024, which claims priority to Chinese Patent Application No 202310317356.7, filed with the China National Intellectual Property Administration on Mar. 28, 2023 and entitled “CIRCUIT BOARD ASSEMBLY”. The applications are hereby incorporated by reference in their entireties.

### TECHNICAL FIELD

The present disclosure relates to the field of electronic devices, in particular, to a circuit board assembly.

### BACKGROUND

A circuit board assembly is provided with at least one chip, which generates heat during operation. It is necessary to lower the temperature of the chip by setting up a heat dissipation component to reduce the possibility of the chip being damaged due to overheating. The reliability of the connection between the heat dissipation component and the chip of some circuit board assemblies may be insufficient, and the heat dissipation component may separate from the chip under an external force, resulting in damage to the circuit board assembly.

### SUMMARY

The present disclosure provides a circuit board assembly to improve the connection reliability between the heat dissipation component and the chip, thereby reducing the possibility of damage to the circuit board due to separation of the heat dissipation component from the chip.

An embodiment of the present disclosure provides a circuit board assembly, including: a circuit board; a chip, fixedly connected to the circuit board; a current-carrying component, fixedly connected to the circuit board; and a heat dissipation component, fixedly connected to the chip and fixedly connected to the current-carrying component.

Further, the current-carrying component includes a positive electrode component and a negative electrode component, the positive electrode component and the negative electrode component are respectively located on both sides of the chip, and the heat dissipation component is fixedly connected to at least the negative electrode component.

Further, the circuit board is provided with a grounding point, and the chip is electrically connected to the grounding point; the heat dissipation component is fixedly connected to the negative electrode component, and the heat dissipation component is insulated from the positive electrode component.

Further, the heat dissipation component is located near an end face of the positive electrode component at a preset distance from the positive electrode component.

Further, the circuit board assembly further includes an insulation component, and the insulation component is located between an end face of the heat dissipation component near the positive electrode component and the positive electrode component.

Further, the circuit board is provided with a grounding point, the heat dissipation component is insulated from the grounding point, the heat dissipation component is fixedly connected to the negative electrode component, and/or the heat dissipation component is fixedly connected to the positive electrode component.

Further, the heat dissipation component includes: a fixing part, where one end of the fixing part is fixedly connected to the chip and the current-carrying component; a plurality of heat dissipation fins, where respective heat dissipation fins are fixed to the other end of the fixing part opposite to the one end, and a heat dissipation channel is formed between adjacent heat dissipation fins.

Further, one end of the fixing part forms one fixing surface, the fixing surface is fixedly connected to the chip, and the fixing surface is fixedly connected to the current-carrying component.

Further, one end of the fixing part forms a plurality of spaced fixing surfaces, part of the fixing surfaces are fixedly connected to the chip, and the other part of the fixing surfaces are fixedly connected to the current-carrying component.

Further, the circuit board assembly has a plurality of chips, which are spaced apart and fixedly connected to the circuit board, and at least one positive electrode component and at least one negative electrode component are located on both sides of each chip; the circuit board assembly has a plurality of heat dissipation components, respective heat dissipation components are fixedly connected to respective chips, and the heat dissipation components are fixedly connected to at least the negative electrode components adjacent to the chips.

An implementation of the present disclosure provides a circuit board assembly, including: a circuit board; a chip fixedly connected to the circuit board; a current-carrying component fixedly connected to the circuit board; and a heat dissipation component fixedly connected to the chip and the current-carrying component. The heat dissipation component being fixedly connected to both the chip and the current-carrying component increases the fixing area of the heat dissipation component, improving the connection reliability of the heat dissipation component, and reducing the possibility of damage to the circuit board assembly caused by detachment of the heat dissipation component. It should be understood that the above general description and the subsequent detailed description are only exemplary and interpretative, and cannot limit the present disclosure.

### BRIEF DESCRIPTION OF DRAWINGS

The accompanying drawings, which are incorporated into the specification and form a part of the specification, illustrates embodiments in accordance with the present disclosure and used together with the specification to explain the principles of the present disclosure.

FIG. 1 is a schematic structural diagram of a circuit board assembly provided in an embodiment of the present disclosure.

FIG. 2 is an equivalent circuit diagram in a case where a heat dissipation component is connected to a negative electrode component in a circuit board assembly provided in an embodiment of the present disclosure.

FIG. 3 is an equivalent circuit diagram in a case where a heat dissipation component is connected to a positive electrode component in a circuit board assembly provided in an embodiment of the present disclosure.

FIG. 4 is a schematic structural diagram of another circuit board assembly provided in an embodiment of the present disclosure.

FIG. 5 is a schematic structural diagram of still another circuit board assembly provided in an embodiment of the present disclosure.

FIG. 6 is a schematic structural diagram of a heat dissipation component in a circuit board assembly provided in an embodiment of the present disclosure.

FIG. 7 is a schematic assembly diagram of a heat dissipation component and a current-carrying component in a circuit board assembly provided in an embodiment of the present disclosure.

FIG. 8 is another schematic assembly diagram of a heat dissipation component and a current-carrying component in a circuit board assembly provided in an embodiment of the present disclosure.

FIG. 9 is a schematic structural diagram of another circuit board assembly provided in an embodiment of the present disclosure.

FIG. 10 is a schematic structural diagram of another circuit board assembly provided in an embodiment of the present disclosure.

FIG. 11 is a schematic structural diagram of another circuit board assembly provided in an embodiment of the present disclosure.

### DESCRIPTION OF REFERENCE NUMBERS

1. circuit board assembly; 10. circuit board; 20. chip; 30. current-carrying component; 31. positive electrode component; 32. negative electrode component; 40. heat dissipation component; 41. fixing part; 42. heat dissipation fin; 43. handle; 50. insulation component.

### DESCRIPTION OF EMBODIMENTS

Exemplary embodiments will be described in detail herein, examples of which are shown in the accompanying drawings. When the following description refers to the drawings, unless otherwise indicated, the same numbers in different accompanying drawings indicate the same or similar elements. The embodiments described in the following exemplary embodiments do not represent all embodiments consistent with the present disclosure. On the contrary, they are only examples of apparatuses consistent with some aspects of the present disclosure as detailed in the appended claims.

After considering the specification and practicing the invention disclosed herein, those of ordinary skill in the art will easily come up with other implementation solution disclosed herein. The present disclosure is intended to cover any variations, uses, or adaptive changes of the present disclosure, and these variations, uses, or adaptive changes follow the general principles of the present disclosure and include common knowledge or conventional technical means in the art that are not disclosed in the present disclosure. The specification and embodiments are only considered exemplary, and the true scope and spirit of the present disclosure are defined by the following claims.

In the following description, the terms “first/second/ . . . ” are only to distinguish different objects and do not imply similarities or relations between them. It should be understood that the orientation descriptions “above”, “below”, “outside”, and “inside” are all directions in normal use, and the “left” and “right” directions represent the left and right directions indicated in the corresponding schematic diagram, which may be or may not be the left or right direction in normal use state.

It should be noted that the terms “include”, “comprise”, or any other variation thereof are intended to encompass nonexclusive inclusion, such that a process, method, article, or apparatus that includes a series of elements not only includes those elements, but also includes other elements that are not explicitly listed or includes elements that are inherent to such a process, method, article, or apparatus. Without further limitations, the element defined by the statement “including a . . . ” does not exclude the existence of other identical elements in the process, method, article, or apparatus that includes that element. The term “connect” includes both direct and indirect connections unless otherwise specified.

In the following specific embodiments, the circuit board assembly can be applied to any electronic device. Exemplarily, the circuit board assembly can be applied to a server, and the circuit board is a processing circuit board of the server. Exemplarily, the circuit board can also be applied to a numerical control machine, and the circuit board is a control circuit board of the numerical control machine. Exemplarily, the circuit board can also be applied to a power supply, and the circuit board is a control circuit board of a power management system of the power supply. For ease of explanation, the following embodiments take the application of the circuit board assembly to a server as an example to illustrate the structure of the circuit board assembly.

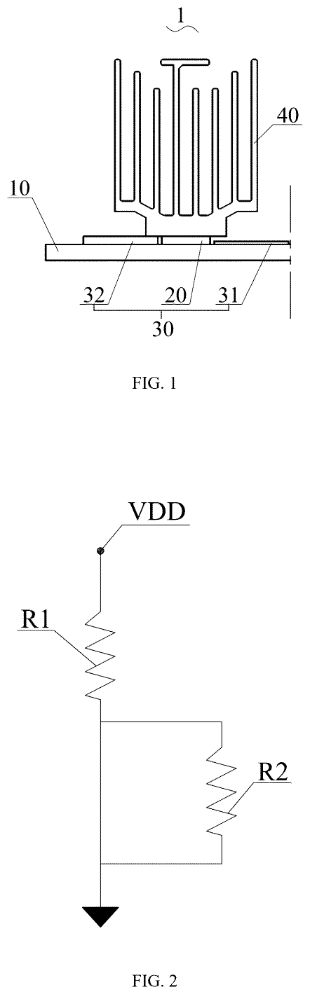

In some embodiments, as shown in FIG. 1, a circuit board assembly 1 includes: a circuit board 10, a chip 20, a current-carrying component 30, and a heat dissipation component 40. The circuit board 10 has a conductive part, and the chip 20 is fixedly connected to the circuit board 10, and the chip 20 is connected to the conductive part of the circuit board 10. At the same time, an electronic component of the circuit board assembly 1 is connected to the conductive part of the circuit board 10 and connected to the chip 20 to form a required circuit. The current-carrying component 30 is fixedly connected to the circuit board 10, and the current-carrying component 30 is connected to the conductive part of the circuit board 10, to enable the current-carrying component 30 to be electrically connected with other electronic components of the circuit board assembly 1.

The heat dissipation component 40 is fixedly connected to the chip 20 and also fixedly connected to the current-carrying component 30, that is, the heat dissipation component 40 is fixedly connected to both the chip 20 and the current-carrying component 30, thereby increasing the fixing area of the heat dissipation component 40 and improving the connection reliability of the heat dissipation component 40. It should be noted that the heat dissipation component 40 can be connected to the chip 20 in any way. Exemplarily, the heat dissipation component 40 can be fixedly connected to the chip 20 through a thermal conductive adhesive or a structural adhesive. Exemplarily, one end face of the chip 20 can be metallized through a backside metallization process, and the heat dissipation component 40 is fixedly connected to the metallized end face of the chip 20 through welding.

An implementation of the present disclosure provides a circuit board assembly, and the electric circuit board assembly includes: a circuit board; a chip fixedly connected to the circuit board; a current-carrying component fixedly connected to the circuit board; and a heat dissipation component fixedly connected to the chip and also fixedly connected to the current-carrying component. The heat dissipation component is fixedly connected to both the chip and the current-carrying component, thereby increasing the fixing area of the heat dissipation component, improving the connection reliability of the heat dissipation component, and reducing the possibility of damage to the circuit board assembly caused by detachment of the heat dissipation component.

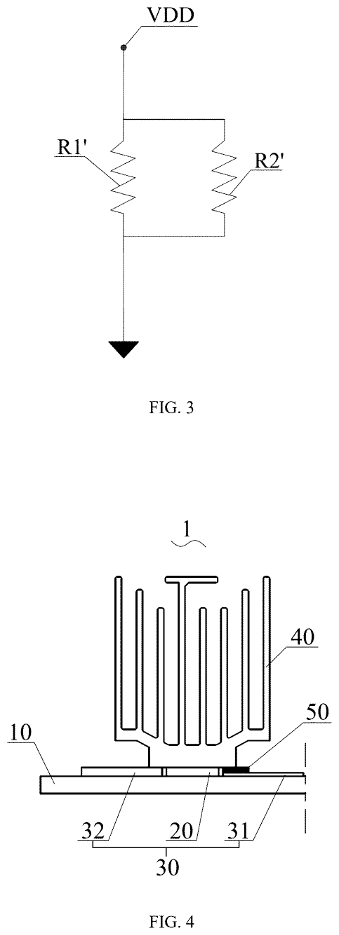

In some embodiments, as shown in FIG. 1, the current-carrying component 30 includes a positive electrode component 31 and a negative electrode component 32. The positive electrode component 31 and the negative electrode component 32 are located on both sides of the chip 20, respectively. The heat dissipation component 40 is fixedly connected to at least the negative electrode component 32. It should be noted that if the chip 20 is electrically connected to a grounding point of the circuit board 10, and the heat dissipation component 40 is electrically connected to the chip 20, then a circuit may be formed between the heat dissipation component 40, the chip 20, and the grounding point of the circuit board 10. The following is a description of the circuits formed between the heat dissipation component 40, the chip 20 and the grounding point of the circuit board 10 when the heat dissipation component 40 is connected to the negative electrode component 32 and the positive electrode component 31, respectively, with reference to FIGS. 2 and 3, and an analysis of the impact of the impedance of the heat dissipation component 40 on the current loss of the chip 20. FIG. 2 is an equivalent circuit diagram formed by the connection of the heat dissipation component 40 and the negative electrode component 32, where a resistor R2 is an equivalent resistance of the heat dissipation component 40 in FIG. 1, a resistor R1 is an equivalent resistance of the chip 20 in FIG. 1, and a wire is connected in series with the resistor R1, the grounding point VDD of the circuit board 10 in FIG. 1, and the ground; meanwhile, the resistor R2 is connected in parallel to the wire. It can be understood that the wire short-circuits the resistor R2, and the current flows from the grounding point VDD of the electric circuit board 10 through the resistor R1 and then to the ground, without flowing through the resistor R2. It should be noted that the resistance value of the resistor R2 is much greater than that of the resistor R1. Exemplarily, the resistance value of the resistor R2 is 5 kiloohms, and the resistance value of the resistor R1 is 5 milliohms. Compared to the electrical energy loss caused by the current flowing through the resistor R2, the electrical energy loss caused by the current flowing through the resistor R1 can be ignored. That is, the connection of the heat dissipation component 40 and the negative electrode component 32 can result in a lower value of electrical current loss. FIG. 3 is an equivalent circuit diagram formed by the connection of the heat dissipation component 40 and the positive electrode component 31, where a resistor R2′ is an equivalent resistance of the heat dissipation component 40 in FIG. 1, a resistor R1′ is an equivalent resistance of the chip 20 in FIG. 1, and the wire is connected in series with the resistor R1′, the grounding point VDD of the circuit board 10 in FIG. 1, and the ground, and the resistor R2′ is connected in parallel to the resistor R1′, and the current flows simultaneously through both the resistor R2′ and the resistor R1′. It should be noted that the resistance value of the resistor R2′ is much greater than that of the resistor R1′. Exemplarily, the resistance value of the resistor R2′ is 5 kiloohms, and the resistance value of the resistor R1′ is 5 milliohms. The current flowing through the resistor R2′ will cause electrical energy to be converted into internal energy, resulting in more electrical energy loss. That is, the connection of the heat dissipation component 40 and the positive electrode component 31 can result in a higher value of electrical current loss. In conclusion, the heat dissipation component 40 can be connected to the negative electrode component 32 in the current-carrying component 30, reducing the dissipation of electrical energy while increasing the connection area of the heat dissipation component 40. Alternatively, the heat dissipation component 40 can also be simultaneously connected to the positive electrode component 31 and the negative electrode component 32 in the current-carrying component 30, further increasing the connection area of the heat dissipation component 40 and improving the connection reliability of the heat dissipation component 40. In a state where the heat dissipation component 40 is simultaneously connected to both the positive electrode component 31 and the negative electrode component 32 in the current-carrying component 30, the equivalent circuit is still shown as FIG. 3.

In some embodiments, the circuit board 10 is provided with a grounding point, and the chip 20 is electrically connected to the grounding point, the heat dissipation component 40 is fixedly connected to the negative electrode component 32, and the heat dissipation component 40 is insulated from the positive electrode component 31. That is, in the absence of insulation between the chip 20 and the grounding point of the circuit board 10, connecting the heat dissipation component 40 to the negative electrode component 32, and insulating the heat dissipation component 40 from the positive electrode component 31, can reduce the electrical energy loss caused by current flowing through the heat dissipation component 40. It should be noted that the insulation between the heat dissipation component 40 and the positive electrode component 31 can be achieved in various ways. Exemplarily, as shown in FIG. 1, the end face of the heat dissipation component 40 near the positive electrode component 31 is separated from the positive electrode component 31 by a predetermined distance, and the insulation between the heat dissipation component 40 and the positive electrode component 31 is achieved through the air between the heat dissipation component 40 and the positive electrode component 31. Optionally, as shown in FIG. 1, the thickness of the negative electrode component 32 is the same as that of the chip 20, and the thickness of the positive electrode component 31 is smaller than that of the negative electrode component 32. Therefore, while fixing the heat dissipation component 40 to the chip 20, the heat dissipation component 40 is fixed to the negative electrode component 32, and there is a preset distance between the heat dissipation component 40 and the positive electrode component 31. Optionally, as shown in FIG. 4, the circuit board assembly 1 also includes an insulation component 50, the insulation component 50 is located between the end face of the heat dissipation component 40 near the positive electrode component 31 and the positive electrode component 31. The insulation between the heat dissipation component 40 and the positive electrode component 31 is achieved through the insulation component 50 between the heat dissipation component 40 and the positive electrode component 31.

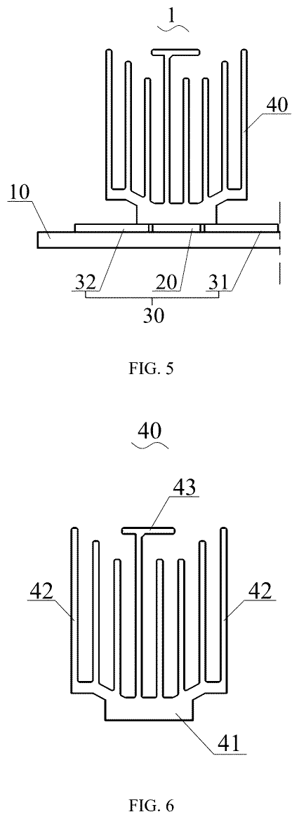

In some embodiments, as shown in FIG. 5, the circuit board 10 is provided with a grounding point, and the heat dissipation component 40 is insulated from the grounding point. This can be understood as the current between the circuit board 10 and the ground does not flow through the heat dissipation component 40, thereby reducing the electrical energy loss caused by the current flowing through the heat dissipation component 40. It should be noted that the insulation between the heat dissipation component 40 and the grounding point can be achieved through different manners. Exemplarily, the insulation between the heat dissipation component 40 and the grounding point can be achieved by insulating the heat dissipation component 40 from the chip 20. For example, a thermally conductive and insulating material can be used for the fixed connection between the heat dissipation component 40 and the chip 20, so that the current flows directly to the ground after flowing through the chip 20 without flowing through the heat dissipation component 40, thereby achieving insulation between the heat dissipation component 40 and the grounding point. Exemplarily, the insulation between the heat dissipation component 40 and the grounding point can also be achieved through the insulation between the chip 20 and the grounding point. For example, the silicon substrate of the chip 20 can be electrically isolated from the grounding point, thereby discommunicating both the chip 20 and the heat dissipation component 40 with the ground, so that current does not flow through either the chip 20 or the heat dissipation component 40. Exemplarily, the insulation between the heat dissipation component 40 and the grounding point can also be achieved by directly providing an insulation structure between the heat dissipation component 40 and the grounding point; meanwhile, the heat dissipation component 40 is fixedly connected to the negative electrode component 32, and the heat dissipation component 40 is fixedly connected to the positive electrode component 31. This can be understood as that in a case where the insulation is formed between the heat dissipation component 40 and the grounding point, the heat dissipation component 40 is also fixedly connected to the positive electrode component 31 and/or the negative electrode component 32 in the current-carrying component 30. Where In the case where the heat dissipation component 40 is fixedly connected to both the positive electrode component 31 and the negative electrode component 32 in the current-carrying component 30, the connection area of the heat dissipation component 40 can be further increased, improving the connection reliability of the heat dissipation component 40, and meanwhile, the current of the current-carrying component 30 will not flow through the heat dissipation component 40, reducing the electrical energy loss caused by the current flowing through the heat dissipation component 40. It should be noted that, in a case where the heat dissipation component 40 is insulated from the grounding point, and the heat dissipation component 40 is fixedly connected to the positive electrode component 31 in the current-carrying component 30, or in a case where the heat dissipation component 40 is fixedly connected to both the positive electrode component 31 and the negative electrode component 32 in the current-carrying component 30, the equivalent circuit diagram is shown in FIG. 3. However, current is prevented from flowing through the heat dissipation component 40 by insulation, thereby further reducing electrical energy loss.

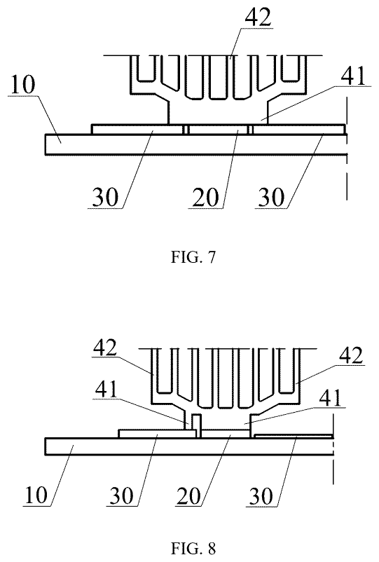

In some embodiments, as shown in FIG. 6, the heat dissipation component 40 includes a fixing part 41 and a plurality of heat dissipation fins 42. One end of the fixing part 41 is fixedly connected to the chip 20 and connected to the current-carrying component 30, each heat dissipation fin 42 is fixed to the other end of the fixing part 41 opposite to the one end, heat of the chip 20 is transferred to the fixing part 41 through thermal conduction, the fixing part 41 transfers the heat to respective heat dissipation fins 42 through thermal conduction, and meanwhile a heat dissipation channel is formed between adjacent heat dissipation fins 42, the heat transferred to respective heat dissipation fins 42 is dissipated into the air through heat exchange with the air flowing through the heat dissipation channel, thereby achieving cooling of the chip 20. Optionally, respective heat dissipation fins 42 are arranged at equal intervals to ensure consistent heat dissipation performance of parts of the heat dissipation component 40, thereby maintaining consistent temperature of parts of the chip 20, that is, ensuring good thermal consistency of parts of the chip 20. Optionally, as shown in FIG. 6, an end of at least one heat dissipation fin 42 away from the fixing part 41 has a handle 43, the handle protrudes from the outer surface of the heat dissipation fin 42 in a direction perpendicular to the extension direction of the heat dissipation fin 42, thereby improving the convenience of installation and disassembly the heat dissipation component 40. In other embodiments, the circuit board assembly is applied in an electronic apparatus, and the electronic apparatus has a ventilation channel that allows airflow to flow in a predetermined direction. The extension direction of the heat dissipation channel formed between respective heat dissipation fins 42 is parallel to the flow direction of the airflow in the ventilation channel, so that air can flow through the heat dissipation channel more quickly and accelerate the speed at which the air takes away the heat from the heat dissipation fin 42, thereby improving the heat dissipation effect of the heat dissipation component 40 on the chip 20 in the circuit board assembly 1. It should be noted that the fixing part 41 is directly fixed to the chip 20, and the fixing part 41 is in contact with or attached to the chip 20 after fixing. The fixing part 41 can be directly fixed to the chip 20 in any form. The following provides an exemplary explanation of the forms of the fixed connection between the fixing part 41 and the chip 20 in conjunction with FIGS. 7 and 8. Those skilled in the art should understand that the connection between the fixing part 41 and the chip 20 can also be in other direct fixing manners besides those shown in FIGS. 7 and 8.

As shown in FIG. 7, one end of the fixing part 41 forms a fixing surface, the fixing surface is fixedly connected to the chip 20, and the fixing surface is fixedly connected to the current-carrying component 30. That is, one end of the fixing part 41 extends to form a continuous plane or curved surface, and is fixedly connected to both the chip 20 and the current-carrying component 30 through the continuous fixing surface. The structure of the fixing part 41 is simple, and it is easy to align the fixing surface with the chip 20 and the current-carrying component 30 during the installation of the heat dissipation component 40, improving the convenience of installing the heat dissipation component 40. As shown in FIG. 8, one end of the fixing part 41 forms a plurality of spaced fixing surfaces. One part of the fixing surface is fixedly connected to the chip 20, and the other part of the fixing surface is fixedly connected to the current-carrying component 30. That is, the chip 20 and the current-carrying component 30 are separately fixed by the spaced fixing surfaces. It should be noted that the fixing surface is a mating surface that needs to be connected to other parts, and has a higher machining accuracy requirement compared with other non-mating surfaces. For example, compared with other non-mating surfaces of the heat dissipation component 40, the fixing surface requires a higher flatness to enable the heat dissipation component 40 to be reliably and fixedly connected to the chip 20 and the current-carrying component 30. By arranging the fixing surface connected to the chip 20 and the fixing surface connected to the current-carrying component 30 separately, the area of the fixing surface of the fixing part 41 can be reduced, and the non-mating surface, which does not need to be connected to the chip 20 and the current-carrying component 30, of the end face of the fixing part 41 away from the heat dissipation fin 42 can be separated, thereby reducing the manufacturing cost of the fixing part 41. Where separated arrangement of respective fixing surfaces of the fixing part 41 can be achieved in various manners. Exemplarily, the number of the fixing part 41 can be one, and the end face of the fixing part 41 away from the heat dissipation fin 42 is provided with a groove, so as to separate the end face into a plurality of spaced fixing surfaces through the groove. Exemplarily, the number of fixing part 41 may be multiple, and multiple fixing parts 41 are spaced apart, so that the end faces of respective fixing parts 41 away from the heat dissipation fins 42 form spaced fixing surfaces.

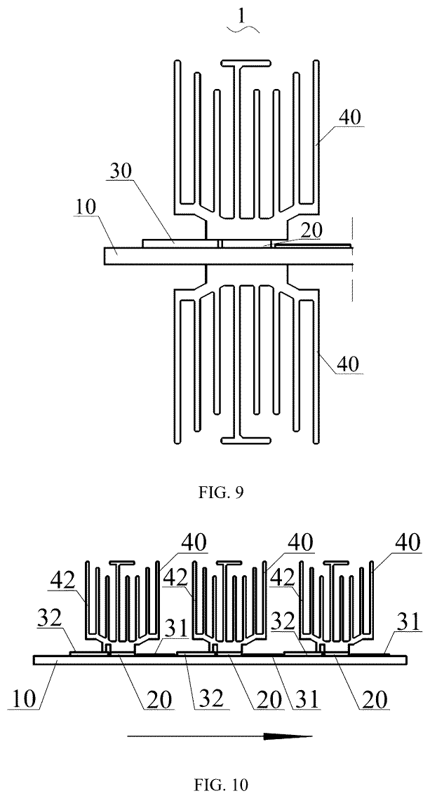

In other embodiments, as shown in FIG. 9, the circuit board 10 has opposite first and second end faces, the first end face has a conductive part, the second end face is an insulating part, and the chip 20 is fixed to the first end face. The circuit board assembly 1 has a plurality of heat dissipation components 40. Part of the heat dissipation components 40 are fixedly connected to the chip 20, and the heat dissipation component 40 fixedly connected to the chip 20 is fixedly connected to the current-carrying component 30; other part of the heat dissipation components 40 are fixed to the second end face, and other part of the heat dissipation components 40 are located near the chip 20. Therefore, the plurality of heat dissipation components 40 fixed to the first and second end faces of the circuit board 10 simultaneously dissipate heat from the chip, thereby improving the cooling capacity of the chip 20 in the circuit board assembly 1. It should be noted that the second end face is an insulating part and does not need to fix an electronic devices and thus the heat dissipation component 40 fixed to the second end face has a large connection area with the second end face, thereby having a high connection reliability; at the same time, the heat dissipation component 40 is insulated from the second end face, and the current of the circuit board 10 will not flow through the heat dissipation component 40 fixed to the second end face, thereby reducing the electrical energy loss caused by the current flowing through the heat dissipation component 40.

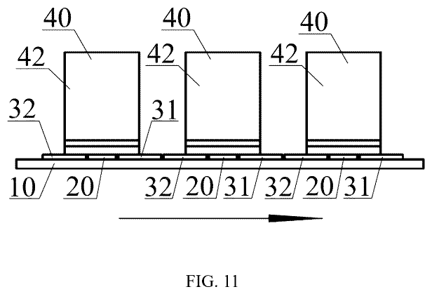

In some embodiments, as shown in FIG. 10, the circuit board assembly 1 has a plurality of chips 20, respective chips 20 are spaced apart and fixedly connected to the circuit board 10, and at least one positive electrode component 31 and at least one negative electrode component 32 are located on both sides of each chip 20, respectively. That is, respective chips 20 are communicated with other electronic devices through the at least one positive electrode component 31 and the at least one negative electrode component 32; or communicated with other chips 20 through the at least one positive electrode component 31 and the at least one negative electrode component 32. Optionally, respective chips 20 are connected in series through the positive electrode component 31 and the negative electrode component 32 to achieve the communication of data information between the chips 20. Optionally, as shown in FIG. 10, respective chips 20 are arranged at intervals along a first direction (indicated by the arrow in FIG. 10), and the extension direction of the heat dissipation channels between respective heat dissipation fins 42 is perpendicular to the first direction. Optionally, as shown in FIG. 11, the heat dissipation channels between respective heat dissipation fins 42 are parallel to the first direction. At the same time, the circuit board assembly 1 has a plurality of heat dissipation components 40, respective heat dissipation components 40 are fixedly connected to respective chips 20, and the heat dissipation components 40 are fixedly connected to the negative electrode components 32 adjacent to the chips 20. It can be understood that respective chips 20 are respectively fixed with one heat dissipation component 40, and respective chips 20 are separately cooled through respective heat dissipation components 40. At the same time, the heat dissipation components 40 connected to the chips 20 are also fixedly connected to the negative electrode components 32 adjacent to the chips 20, thereby increasing the connection area of the heat dissipation components 40 and increasing the connection reliability of the heat dissipation components 40. Where the heat dissipation component 40 is connected to at least the negative electrode component 32, which can be understood as the heat dissipation component 40 is only fixedly connected to the negative electrode component 32 in the current-carrying component, thereby reducing the electrical energy loss caused by the current flowing through the heat dissipation component 40 in a case where the heat dissipation component 40 is not insulated from the grounding point of the circuit board 10. Alternatively, the heat dissipation component 40 can be fixedly connected to both the positive electrode component 31 and the negative electrode component 32 in the current-carrying component, thereby further increasing the connection area of the heat dissipation component 40 and enhancing the connection reliability of the heat dissipation component 40. Optionally, the heat dissipation component 40 can also be insulated from the grounding point of the circuit board 10, thereby reducing the electrical energy loss caused by current flowing through the heat dissipation component 40 while increasing the connection area of the heat dissipation component 40.

It should be understood that the present disclosure is not limited to the precise structure described above and shown in the accompanying drawings, and various modifications and changes can be made without departing from its scope. The scope of the present disclosure is limited only by the appended claims.

What is claimed is:

1. A circuit board assembly, comprising:
a circuit board;
a chip, fixedly connected to the circuit board;
a current-carrying component, fixedly connected to the circuit board; and
a heat dissipation component, fixedly connected to the chip and the current-carrying component.

2. The circuit board assembly according to claim 1, wherein the current-carrying component comprises a positive electrode component and a negative electrode component, the positive electrode component and the negative electrode component are respectively located on both sides of the chip, and the heat dissipation component is fixedly connected to at least the negative electrode component.

3. The circuit board assembly according to claim 2, wherein the circuit board is provided with a grounding point, and the chip is electrically connected to the grounding point; the heat dissipation component is fixedly connected to the negative electrode component, and the heat dissipation component is insulated from the positive electrode component.

4. The circuit board assembly according to claim 3, wherein the heat dissipation component is located near an end face of the positive electrode component at a preset distance from the positive electrode component.

5. The circuit board assembly according to claim 3, wherein the circuit board assembly further comprises an insulation component, and the insulation component is located between an end face of the heat dissipation component near the positive electrode component and the positive electrode component.

6. The circuit board assembly according to claim 2, wherein the circuit board is provided with a grounding point, the heat dissipation component is insulated from the grounding point, the heat dissipation component is fixedly connected to at least one of the negative electrode component or the positive electrode component.

7. The circuit board assembly according to claim 1, wherein the heat dissipation component comprises:
a fixing part, one end of which is fixedly connected to the chip and the current-carrying component; and
a plurality of heat dissipation fins, wherein respective heat dissipation fins are fixed to the other end of the fixing part opposite to the one end, and a heat dissipation channel is formed between adjacent heat dissipation fins.

8. The circuit board assembly according to claim 2, wherein the heat dissipation component comprises:
a fixing part, one end of which is fixedly connected to the chip and the current-carrying component; and
a plurality of heat dissipation fins, wherein respective heat dissipation fins are fixed to the other end of the fixing part opposite to the one end, and a heat dissipation channel is formed between adjacent heat dissipation fins.

9. The circuit board assembly according to claim 3, wherein the heat dissipation component comprises:
a fixing part, one end of which is fixedly connected to the chip and the current-carrying component; and
a plurality of heat dissipation fins, wherein respective heat dissipation fins are fixed to the other end of the fixing part opposite to the one end, and a heat dissipation channel is formed between adjacent heat dissipation fins.

10. The circuit board assembly according to claim 4, wherein the heat dissipation component comprises:
a fixing part, one end of which is fixedly connected to the chip and the current-carrying component; and
a plurality of heat dissipation fins, wherein respective heat dissipation fins are fixed to the other end of the fixing part opposite to the one end, and a heat dissipation channel is formed between adjacent heat dissipation fins.

11. The circuit board assembly according to claim 5, wherein the heat dissipation component comprises:
a fixing part, one end of which is fixedly connected to the chip and the current-carrying component; and
a plurality of heat dissipation fins, wherein respective heat dissipation fins are fixed to the other end of the fixing part opposite to the one end, and a heat dissipation channel is formed between adjacent heat dissipation fins.

12. The circuit board assembly according to claim 6, wherein the heat dissipation component comprises:
a fixing part, one end of which is fixedly connected to the chip and the current-carrying component; and
a plurality of heat dissipation fins, wherein respective heat dissipation fins are fixed to the other end of the fixing part opposite to the one end, and a heat dissipation channel is formed between adjacent heat dissipation fins.

13. The circuit board assembly according to claim 7, wherein one end of the fixing part forms a fixing surface, the fixing surface is fixedly connected to the chip, and the fixing surface is fixedly connected to the current-carrying component.

14. The circuit board assembly according to claim 7, wherein one end of the fixing part forms a plurality of spaced fixing surfaces, part of the fixing surfaces are fixedly connected to the chip, and the other part of the fixing surfaces are fixedly connected to the current-carrying component.

15. The circuit board assembly according to claim 2, wherein the circuit board assembly has a plurality of chips, which are spaced apart and fixedly connected to the circuit board, and at least one positive electrode component and at least one negative electrode component are located on both sides of each chip; the circuit board assembly has a plurality of heat dissipation components, respective heat dissipation component are fixedly connected to respective chips, and the heat dissipation components are fixedly connected to at least the negative electrode components adjacent to the chips.
